(19) United States
(12) Patent Application Publication
(10) Pub. No.: US 2017/0047309 A1
(43) Pub. Date: Feb. 16, 2017

(54) FABRICATING METHOD OF SEMICONDUCTOR DEVICE

(71) Applicant: Samsung Electronics Co., Ltd., Suwon-si (KR)

(72) Inventors: Seung-Duk BAEK, Hwaseong-si (KR); Jong-Bo SHIM, Asan-si (KR); Tae-Je CHO, Yongin-si (KR)

(73) Assignee: Samsung Electronics Co., Ltd., Suwon-si (KR)

(21) Appl. No.: 15/158,921

(22) Filed: May 19, 2016

(30) Foreign Application Priority Data
Aug. 12, 2015 (KR) 10-2015-0113781

(51) Int. Cl. H01L 25/065; H01L 25/00

(52) U.S. Cl. CPC H01L 25/0657; H01L 25/50; H01L 2225/06513; H01L 2225/06544; H01L 2225/06555; H01L 2225/06582; H01L 2225/06589

(57) ABSTRACT

A fabricating method of a semiconductor device, in which a first semiconductor chip having a desired first thickness and a semiconductor chip having a desired second thickness are used to fabricate a semiconductor device having a desired third thickness that is greater than the sum of the first and second thicknesses includes providing the first semiconductor chip, which has the first thickness, forming the second semiconductor chip, which is connected to the first semiconductor chip via through silicon vias (TSVs) and has the second thickness, on the first semiconductor chip, and providing a dummy semiconductor chip, which is not electrically connected to the semiconductor chip and has a fourth thickness, on the second semiconductor chip, wherein the fourth thickness is generated based on a difference between about the third thickness and about a sum of the first and second thicknesses.

This U.S. non-provisional application claims the benefit of priority under 35 U.S.C. §119 to Korean Patent Application No. 10-2015-0113781 filed on Aug. 12, 2015, in the Korean Intellectual Property Office, the disclosure of which is incorporated herein by reference in its entirety.

### BACKGROUND

### Technical Field

At least one example embodiment of the inventive concepts relates to a semiconductor device, and more particularly, to a semiconductor device including a dummy semiconductor chip.

Description of the Related Art

In the electronic industry such as the semiconductor industry, the demand for multi-chip stacking has become greater due to growing demands for high bandwidth and high storage capacity. Processors such as central processing units (CPUs) and/or graphics processing units (GPUs) have evolved to have high performance. Thus, the “system-required” data processing speed (bandwidth: number of I/O pins×data processing speed of each I/O pin) of memories has exponentially increased. Against this backdrop, new memory products such as Wide I/O memories [number of I/O pins: 512] or High Bandwidth Memories (HBMs) [number of signal I/O pins: 1024] have been developed. Further developments are expected in Wide I/O-type memory techniques.

### SUMMARY

At least one example embodiment relates to a fabricating method of a semiconductor device including a dummy semiconductor chip, which is arranged on a semiconductor chip to reduce a size of the semiconductor chip.

At least one example embodiment relates to a semiconductor device including a dummy semiconductor chip, which is arranged on a semiconductor chip to reduce the size of the semiconductor chip.

In at least one example embodiment, a fabricating method of a semiconductor device, in which a first semiconductor chip having a desired (and/or alternatively predetermined) first thickness and a semiconductor chip having a desired (and/or alternatively predetermined) second thickness are used to fabricate a semiconductor device having a desired (and/or alternatively predetermined) third thickness that is greater than the sum of the first and second thicknesses. The fabricating method comprises providing the first semiconductor chip, which has the first thickness, providing the second semiconductor chip, which is connected to the first semiconductor chip via through silicon vias (TSVs) and has the second thickness, on the first semiconductor chip, and providing a dummy semiconductor chip, which is not electrically connected to the semiconductor chip and has a fourth thickness, on the second semiconductor chip. The fourth thickness is determined in consideration of the difference between the third thickness and the sum of the first and second thicknesses.

in at least one example embodiment, a fabricating method of a semiconductor device comprises providing first and second semiconductor chips, which are horizontally spaced from each other on a wafer. The first and second semiconductor chips have a desired (and/or alternatively predetermined) first thickness. The method also includes, connecting each of the first and second semiconductor chips to the wafer via TSVs, providing a dummy wafer, which is not electrically connected to the first and second semiconductor chips and has a second thickness, on the first and second semiconductor chips, and providing a first semiconductor device including the first semiconductor chip and a second semiconductor device including the second semiconductor chip by sawing the wafer and the dummy wafer. The first and second semiconductor devices have a desired (and/or alternatively predetermined) third thickness and the second thickness is determined in consideration of the difference between the third thickness and the first thickness.

In at least one example embodiment, a method of fabricating a semiconductor device includes providing at least two semiconductor chips on a substrate, the at least two semiconductor chips having a combined first thickness, electrically connecting the at least two semiconductor chips, providing a dummy semiconductor chip on one of the at least two semiconductor chips, the dummy semiconductor chip having a second thickness, and providing at least one semiconductor device having a desired third thickness, the desired third thickness greater than the first thickness.

In at least one example embodiment, the at least two semiconductor chips are electrically connected via through silicon vias.

In at least one example embodiment, the method may include forming an insulating layer at least partially around the at least two semiconductor chips.

In at least one example embodiment, the method may include forming a passivation layer at least partially around the insulating layer and the dummy semiconductor chip.

In at least one example embodiment, a width of the dummy semiconductor chip, which overlaps the semiconductor device, is different from a width of the at least one semiconductor chip.

At least some example embodiments of the inventive concepts are not restricted to the one set forth herein. The above and other example embodiments of the inventive concepts will become more apparent to one of ordinary skill in the art to which the inventive concepts pertain by referencing the detailed description of the example embodiments of the inventive concepts given below.

Other features and aspects will be apparent from the following detailed description, the drawings, and the claims.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1 is a flowchart illustrating a fabricating method of a semiconductor device, according to at least one example embodiment.

FIGS. 2 to 6 are cross-sectional views illustrating intermediate operations of the fabricating method according to at least one example embodiment.

FIG. 7 is a cross-sectional view of a semiconductor device obtained by the fabricating method according to at least one example embodiment.

FIG. 8 is a cross-sectional view of the semiconductor device 100.

FIGS. 9 and 10 are cross-sectional views showing a width of a scribe lane of a semiconductor wafer according to the thickness of a semiconductor chip in the fabricating method according to at least one example embodiment.

FIG. 11 is a cross-sectional view of a semiconductor device according to at least one example embodiment.

FIGS. 12 to 18 are cross-sectional views illustrating intermediate operations of a fabricating method of a semiconductor device according to at least one example embodiment.

FIG. 19 is a cross-sectional view of a semiconductor device obtained by the fabricating method according to at least one example embodiment.

FIG. 20 is a cross-sectional view of a semiconductor device according to at least one example embodiment.

FIG. 21 is a schematic view of a semiconductor system to which a semiconductor device can be applied according to at least one example embodiment.

### DETAILED DESCRIPTION OF THE EMBODIMENTS

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It should be understood that, although the terms first, second, third, etc. may be used herein to describe various elements, components, regions, layers and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of example embodiments.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

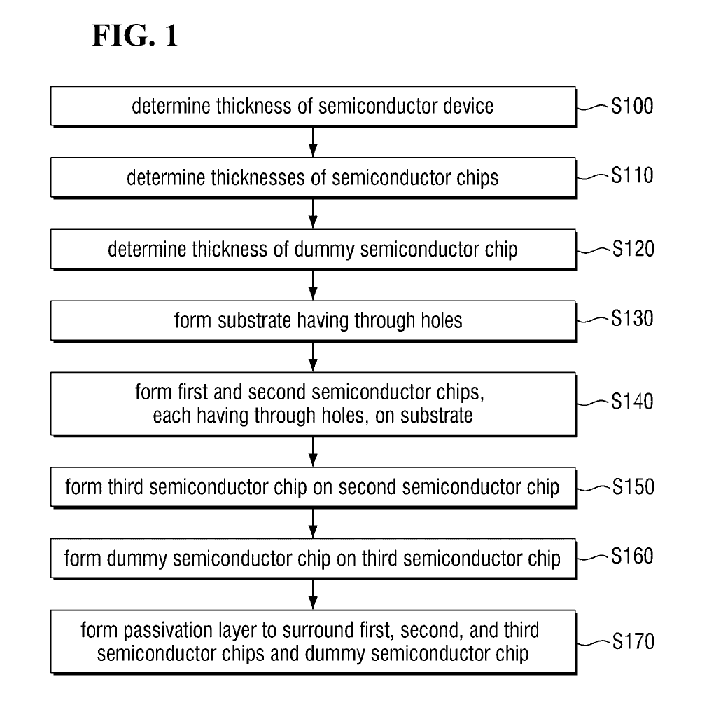

A fabricating method of a semiconductor device, according to at least one example embodiment of the inventive concepts, will hereinafter be described with reference to FIG. 1.

FIG. 1 is a flowchart illustrating a fabricating method of a semiconductor device, according to at least one example embodiment of the inventive concepts.

Referring to FIG. 1, in S100, the thickness of a semiconductor device may be determined. In subsequent processes to S100, the sum of the thicknesses of first, second, and third semiconductor chips and the thickness of a dummy semiconductor chip may be smaller than the thickness of the semiconductor device.

In S110, the thicknesses of the first, second, and third semiconductor chips may be determined. The first, second, and third semiconductor chips may have the same thickness or different thicknesses. More specifically, in the semiconductor device, the first and second semiconductor chips may have the same thickness. The third semiconductor chip may be thicker than the first and second semiconductor chips. However, the inventive concepts are not limited to this. That is, in at least one example embodiment of the inventive concepts, the third semiconductor chip may be thinner than the first and second semiconductor chips.

In S120, the thickness of the dummy semiconductor chip may be about a difference between the thickness of the semiconductor device and the sum of the thicknesses of the first, second, and third semiconductor chips. That is, the thickness of the dummy semiconductor chip may be determined using the following equation: Thickness of Semiconductor Device−(Thickness of First Semiconductor Chip+Thickness of Second Semiconductor Chip+Thickness of Third Semiconductor Chip)>Thickness of Dummy Semiconductor Chip.

Due to the presence of the dummy semiconductor chip, the thicknesses of the first, second, and third semiconductor chips may be uniformly maintained to be equal to one another or to be relatively small. That is, the thicknesses of the first, second, and third semiconductor chips may be reduced by increasing the thickness of the dummy semiconductor chip.

In S130, a substrate having through holes may be prepared. The through holes may be provided to penetrate the substrate along a direction perpendicular to the horizontal plane of the substrate. Connectors may be provided on the top and bottom surfaces of the substrate.

In S140, the first and second semiconductor chips may be formed and/or provided on the substrate having the through holes. The first and second semiconductor chips may be sequentially stacked on the substrate so as to form a stack structure. The first and second semiconductor substrates may be disposed on the substrate to be parallel to the substrate. The first and second semiconductor substrates may be electrically connected to the substrate via through silicon vias (TSVs) and/or connectors.

In S150, the third semiconductor chip may be formed on the second semiconductor chip. The third semiconductor chip may be disposed on the second semiconductor chip to be parallel to the second semiconductor chip. The third semiconductor chip may be electrically connected to the second semiconductor chip via TSVs and/or connectors.

In S160, the dummy semiconductor chip may be formed on the third semiconductor chip. The dummy semiconductor chip may be disposed on the third semiconductor chip to be parallel to the third semiconductor chip. The dummy semiconductor ship may not be electrically connected to the substrate and the first, second, and third semiconductor chips.

In S170, a passivation layer may be formed to surround the first, second, and third semiconductor chips and the dummy semiconductor chip.

FIG. 1 schematically illustrates a fabricating method of a semiconductor device, according to at least one example embodiment of the inventive concepts, and the fabricating method according to the at least one example embodiment of FIG. 1 will hereinafter be described in further detail.

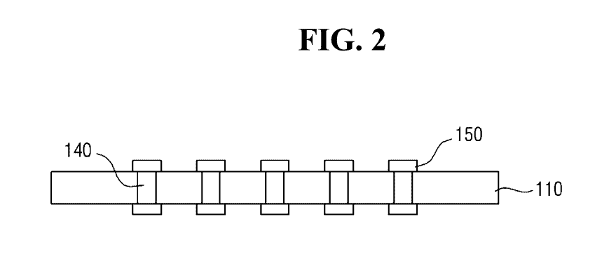

The fabricating method according to the at least one example embodiment of FIG. 1 and a semiconductor device obtained by the fabricating method according to the at least one example embodiment of FIG. 1 will hereinafter be described with reference to FIGS. 2 to 7.

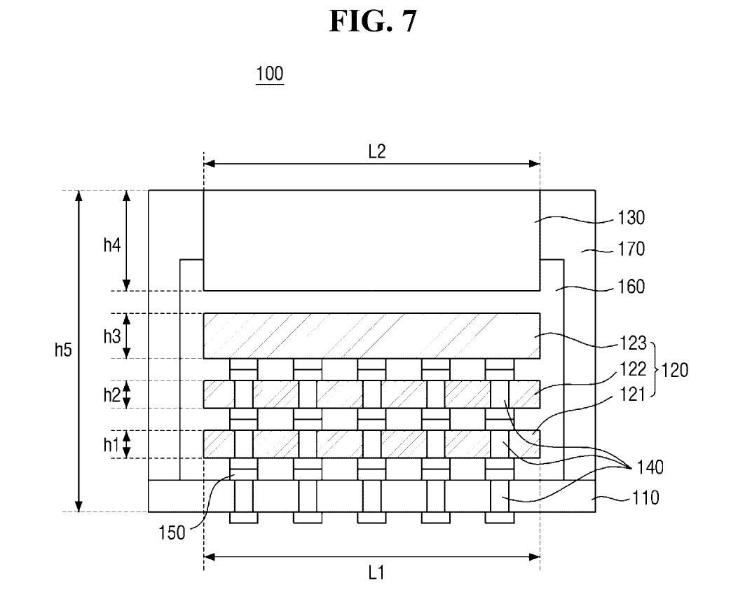

FIGS. 2 to 6 are cross-sectional views illustrating intermediate operations of the fabricating method according to the at least one example embodiment of FIG. 1. FIG. 7 is a cross-sectional view of a semiconductor device obtained by the fabricating method according to the at least one example embodiment of FIG. 1.

Referring to FIG. 2, through holes 140 may be formed to penetrate a substrate 110 in a direction perpendicular to the horizontal plane of the substrate 110. The through holes 140 may be formed in the substrate 110 using a mask pattern. The mask pattern may contain an organic material. The organic material may be at least one of silicon nitride, silicon oxynitride, or photoresist. The through holes 140 may be formed by etching the substrate 110 using the mask pattern as a patterning mask. After the formation of the through holes 140, the mask pattern may be removed.

After the formation of the through holes 140, connectors 150 may be formed on the top and bottom surfaces of the substrate 110. The connectors 150 may be connected to both ends of a corresponding through hole 140. As a result, the substrate 110 and a plurality of semiconductor chips 120 may be electrically connected.

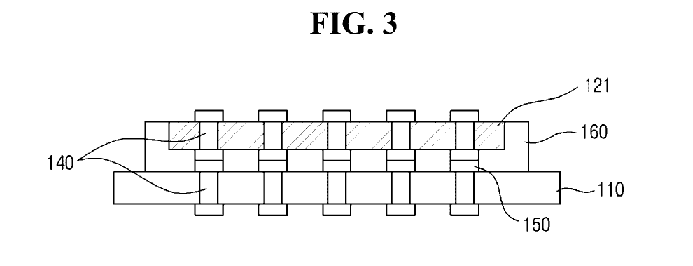

Referring to FIG. 3, connectors 150 may be formed to be connected to the connectors 150 formed on the top surface of the substrate 110. A first semiconductor chip 121 may be formed and/or provided on the substrate 110 to be connected to the connectors 150 formed on the top surface of the substrate 110 and to be parallel to the substrate 110. The first semiconductor chip 121 may be formed and/or provided on the substrate 110 through thermal compression bonding. After the formation of the first semiconductor chip 121, connectors 150 may be formed on the top surface of the first semiconductor chip 121 to be connected to first ends of through holes 140 formed in the first semiconductor chip 121.

In at least one example embodiment, through holes 140 may be formed in the first semiconductor chip 121 using a mask pattern. The through holes 140 of the first semiconductor chip 121 may be formed after the formation of the first semiconductor chip 121 on the substrate 110, but the inventive concepts are not limited thereto. That is, in at least one example embodiment of the inventive concepts, the through holes 140 of the first semiconductor chip 121 may be formed first. Then, the first semiconductor chip 121 may be formed on the substrate 110. The substrate 110 and the first semiconductor chip 121 may be electrically connected through the through holes 140 of the substrate 110 and the through holes 140 of the first semiconductor chip 121.

In at least one example embodiment, after the formation of the first semiconductor chip 121, an insulating layer 160 may be formed on the substrate 110 to surround the connectors 150 formed on the bottom surface of the first semiconductor chip 121 and the first semiconductor chip 121. The insulating layer 160 may be formed so that the insulating layer 160 does not overlap edges of the substrate 110. That is, the insulating layer 160 may be formed on only part of the substrate 110 and may not be formed on the edges of the substrate 110. The insulating layer 160 may be formed to about the same height as the top surface of the first semiconductor chip 121, but the inventive concepts are not limited thereto.

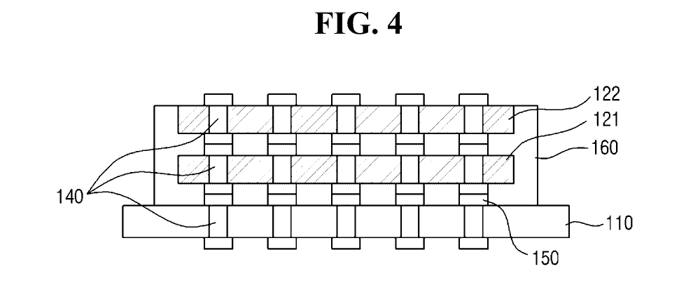

In at least one example embodiment, as shown in FIG. 4, connectors 150 may be formed to connect to the connectors 150 formed on the top surface of the first semiconductor chip 121. A second semiconductor chip 122 may be formed on the first semiconductor chip 121 to connect to the connectors 150 formed on the top surface of the first semiconductor chip 121 and to be parallel to the first semiconductor chip 121. The second semiconductor chip 122 may be formed and/or provided on the first semiconductor chip 121 through thermal compression bonding. After the formation of the second semiconductor chip 122, connectors 150 may be formed on the top surface of the second semiconductor chip 122 to be connected to first ends of through holes 140 formed in the second semiconductor chip 122.

In at least one example embodiment, through holes 140 may be formed in the second semiconductor chip 122 using a mask pattern. The through holes 140 of the second semiconductor chip 122 may be formed after the formation of the second semiconductor chip 122 on the first semiconductor chip 121, but the inventive concepts are not limited thereto.

In at least one example embodiment of the inventive concepts, the through holes 140 of the second semiconductor chip 122 may be formed first. Then, the second semiconductor chip 122 may be formed on the first semiconductor chip 121. The substrate 110, the first semiconductor chip 121, and the second semiconductor chip 122 may be electrically connected through the through holes 140 of the substrate 110, the through holes 140 of the first semiconductor chip 121, and the through holes 140 of the second semiconductor chip 122.

In at least one example embodiment, after the formation of the second semiconductor chip 122, an insulating layer 160 may be formed on the first semiconductor chip 121 and the insulating layer 160 of FIG. 3. The insulating layer 160 may surround the connectors 150 formed on the bottom surface of the second semiconductor chip 122 and the second semiconductor chip 122. The insulating layer 160 of FIG. 4 may overlap the insulating layer 160 of FIG. 3. The insulating layer 160 of FIG. 4 may be about the same height as the top surface of the second semiconductor chip 122, but the inventive concepts are not limited thereto.

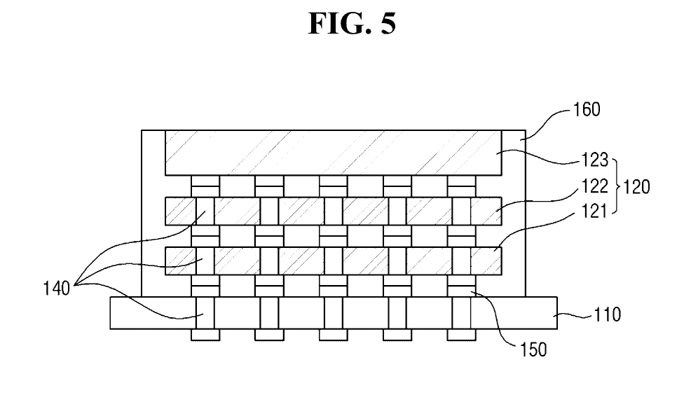

Referring to FIG. 5, connectors 150 may be formed to be connected to the connectors 150 formed on the top surface of the second semiconductor chip 122. A third semiconductor chip 123 may be formed on the second semiconductor chip 122 to be connected to the connectors 150 formed on the top surface of the second semiconductor chip 122 and to be parallel to the second semiconductor chip 122. The third semiconductor chip 122 may be formed on the second semiconductor chip 122 through thermal compression bonding.

In at least one example embodiment, as shown in FIG. 5, the third semiconductor chip 123 may not include any through holes 140, but the inventive concepts are not limited thereto. That is, in some example embodiments of the inventive concepts, the third semiconductor chip 123 may include through holes 140.

In response to the third semiconductor chip 123 including through holes 140, the through holes 140 may be formed in the third semiconductor chip 123 using a mask pattern. The through holes 140 may be formed after the formation of the third semiconductor chip 123 on the second semiconductor chip 122, but the inventive concepts are not limited thereto. That is, in some example embodiments of the inventive concepts, the through holes 140 may be formed in the third semiconductor chip 123. Then, the third semiconductor chip 123 may be formed on the second semiconductor chip 122.

The substrate 110, the first semiconductor chip 121, the second semiconductor chip 122, and the third semiconductor chip 123 may be electrically connected through the through holes 140 of the substrate 110, the through holes 140 of the first semiconductor chip 121, and the through holes 140 of the second semiconductor chip 122, regardless of the presence of through holes 140 in the third semiconductor chip 123.

After the formation of the second semiconductor chip 122, an insulating layer 160 may be formed on the second semiconductor chip 122 and the insulating layer 160 of FIG. 4. The insulating layer 160 may surround the connectors 150 formed on the bottom surface of the third semiconductor chip 123 and the third semiconductor chip 122. The insulating layer 160 of FIG. 5 may be formed to overlap the insulating layer 160 of FIG. 4. The insulating layer 160 of FIG. 5 may be about the same height as the top surface of the third semiconductor chip 123, but the inventive concepts are not limited thereto.

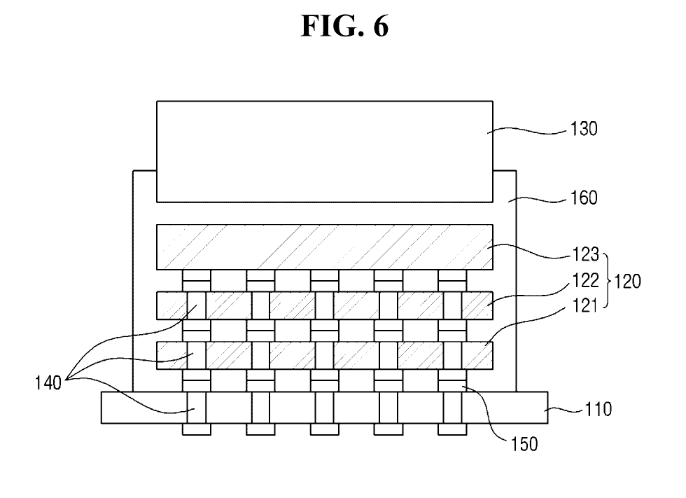

Referring to FIG. 6, after the formation of the third semiconductor chip 123, a dummy semiconductor chip 130 may be formed and/or provided on the third semiconductor chip 123. The dummy semiconductor chip 130 may be parallel to the third semiconductor chip 123. After the formation of the dummy semiconductor chip 130, an insulating layer 160 may be formed to surround a lower part of the dummy semiconductor chip 130, but the inventive concepts are not limited thereto. That is, in some example embodiments of the inventive concepts, the insulating layer 160 of FIG. 6 may be formed on the dummy semiconductor chip 130. The dummy semiconductor chip 130 may be formed on the third semiconductor chip 123 through thermal compression bonding.

Alternatively to the at least one example embodiment of FIG. 6, an insulating layer 160 may be formed to contact only the bottom surface of the dummy semiconductor chip 130 without surrounding the sides of the dummy semiconductor chip. In at least one example embodiment, a passivation layer 170 may be formed. The passivation layer 170 may surround the sides of the dummy semiconductor chip 130.

In at least one example embodiment, as shown in FIG. 7, a width L2 of the dummy semiconductor chip 130 is about the same as a width L1 of the semiconductor chips 120, but the inventive concepts are not limited thereto. That is, in at least one example embodiment of the inventive concepts, the width L2 of the dummy semiconductor chip 130 may differ from the width L1 of the semiconductor chips 120. That is, in at least one example embodiment of the inventive concepts, the width L2 of the dummy semiconductor chip 130 may be larger than, or smaller than, the width L1 of the semiconductor chips 120.

After the formation of the dummy semiconductor chip 130, the passivation layer 170 may be formed on the substrate 110. The passivation layer 170 may surround the sides of each of the insulating layers 160 and the sides of the dummy semiconductor chip 130. In response to the insulating layers 160 being formed to only partially surround the semiconductor chips 120, the passivation layer 170 may surround parts of the semiconductor chips 120 that are not surrounded by the insulating layers 160, the sides of each of the insulating layers 160, and the sides of the dummy semiconductor chip 130. The passivation layer 170 may not be formed on the top surface of the dummy semiconductor chip 130, but the inventive concepts are not limited thereto. That is, in at least one example embodiment of the inventive concepts, the passivation layer 170 may at least partially cover the top surface of the dummy semiconductor chip 130.

A semiconductor device 100 of FIG. 7 may be fabricated using the processes illustrated in FIGS. 2 to 6. According to a fabricating method of the semiconductor device 100, the thickness of the semiconductor 100 may be determined in advance, but the inventive concepts are not limited thereto. That is, in embodiment of the inventive concepts, the thickness of the semiconductor device 100 may not be determined in advance.

A semiconductor device obtained by the fabricating method according to at least one example embodiment, as shown in FIGS. 1 to 6, i.e., the semiconductor device 100, will hereinafter be described with reference to FIG. 7.

Referring to FIG. 7, the semiconductor device 100 includes the substrate 110, the first semiconductor chip 121, the second semiconductor chip 122, the third semiconductor chip 123, the dummy semiconductor chip 130, the through holes 140, the connectors 150, the insulating layers 170, and the passivation layer 170.

The substrate 110 may be a semiconductor wafer-based silicon substrate. In at least one example embodiment of the inventive concepts, the substrate 100 may be a packaging substrate. For example, the substrate 100 may be a printed circuit board (PCB).

In at least one example embodiment, the substrate 110 may be, for example, a bulk silicon substrate. Alternatively, the substrate 110 may be a silicon substrate or may contain another material. For example, the substrate 110 may contain silicon germanium, indium antimonide, lead telluride, indium arsenide, indium phosphide, gallium arsenide, or gallium antimonide. Alternatively, the substrate 110 may be a base substrate with an epitaxial layer disposed thereon.

In at least one example embodiment, the substrate 110 may include the through holes 140. The through holes 140 may be formed to penetrate the substrate 110 in a direction perpendicular to the horizontal plane of the substrate 110.

For example, the through holes 140 may be formed by etching the substrate 110 using a mask pattern. The mask pattern may contain an organic material. The organic material may include at least one of silicon nitride, silicon oxynitride, or photoresist.

In at least one example embodiment, the through holes 140 may be provided in the substrate 110 by using a mask pattern. The mask pattern may contain an organic material. The organic material may include at least one of silicon nitride, silicon oxynitride, or photoresist. The through holes 140 may be formed by etching the substrate 110 using the mask pattern as a patterning mask. After the formation of the through holes 140, the mask pattern may be removed.

In at least one example embodiment, a through hole liner layer (not illustrated) and a through hole barrier layer (not illustrated) may be conformally formed on the inner walls of the through holes 140. The through hole liner layer may contain an insulating material, such as silicon oxide. For example, the through hole liner layer may be formed by atomic layer deposition (ALD), plasma enhanced chemical vapor deposition (PECVD), or sub-atmosphere chemical vapor deposition (SACVD). Alternatively, the through hole liner layer may be formed by thermally oxidizing the inner sidewalls of the through holes 140 through thermal oxidation.

In at least one example embodiment, the through hole barrier layer may be conformally formed on the through hole liner layer through physical vapor deposition (PVD) or metal organic chemical vapor deposition (MOCVD). The through hole barrier layer may contain at least one of titanium (Ti), titanium nitride (TiN), titanium tungsten (TiW), tantalum (Ta), tantantalum nitride (TaN), tungsten (W), or tungsten nitride (WN). The through hole barrier layer may be formed as a single-layer or multi-layer.

In at least one example embodiment, a through hole wiring material layer (not illustrated) may be provided in the through holes 140. The through hole wiring material layer may be formed by electroplating (EP). The through hole wiring material layer may contain at least one of aluminum (Al), gold (Au), beryllium (Be), bismuth (Bi), cobalt (Co), copper (Cu). hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), Ta, telium (Te), Ti, W, zinc (Zn), and zirconium (Zr), but the inventive concepts are not limited thereto.

In at least one example embodiment, the connectors 150 may be on the top and bottom surfaces of the substrate 110. More specifically, the connectors 150 may be connected to both ends of a corresponding through holes 140.

In at least one example embodiment, the connectors 150 may connect the substrate 110 and the semiconductor chips 120. The substrate 110 and the semiconductor chips 120 on the substrate 110 may be electrically connected via TSVs and/or the connectors 150.

In at least one example embodiment, the semiconductor chips 120 may include the first, second, and third semiconductor chips 121, 122, and 123. The first, second, and third semiconductor chips 121, 122, and 123 may be on the substrate 110. For example, the first, second, and third semiconductor chips 121, 122, and 123 may be sequentially stacked on the substrate 110 in a vertical direction so as to form a stack structure.

In at least one example embodiment, the first semiconductor chip 121 may be disposed on the substrate 110 to be parallel to the substrate 110. The first semiconductor chip 121 may be electrically connected to the substrate 110 via the TSVs and/or the connectors 150. The second semiconductor chip 122 may be disposed on the first semiconductor chip 121 to be parallel to the first semiconductor chip 121. The second semiconductor ship 122 may be electrically connected to the first semiconductor chip 121 via the TSVs and/or the connectors 150. The third semiconductor chip 123 may be disposed on the second semiconductor chip 122 to be parallel to the second semiconductor chip 122. The third semiconductor ship 123 may be electrically connected to the second semiconductor chip 122 via the TSVs and the connectors 150. That is, the first, second, and third semiconductor chips 121, 122, and 123 may be on the substrate 110 and may be parallel to the substrate 110. The first, second, and third semiconductor chips 121, 122, and 123 may be electrically connected to the substrate 110 via the TSVs and/or the connectors 150.

In at least one example embodiment, the first semiconductor chip 121 may include the through holes 140. The through holes 140 may be provided in the first semiconductor chip 121. The through holes 140 may penetrate the first semiconductor chip 121 in a direction perpendicular to the horizontal plane of the first semiconductor chip 121. The second semiconductor chip 122 may include the through holes 140. The through holes 140 may penetrate the second semiconductor chip 122 in a direction perpendicular to the horizontal plane of the second semiconductor chip 122.

In at least one example embodiment, the substrate 110, the first semiconductor chip 121, and the second semiconductor chip 122 may include the through holes 140, but the third semiconductor chip 123 and the dummy semiconductor chip 130 may not include the through holes 140. However, the inventive concepts are not limited to this example embodiment. That is, in at least one example embodiment of the inventive concepts, the third semiconductor chip 123 may include the through holes 140.

In at least one example embodiment, in response to the third semiconductor chip 123 including the through holes 140, the through holes 140 may be provided in the third semiconductor chip 123. The through holes 140 may penetrate the third semiconductor chip 123 in a direction perpendicular to the horizontal plane of the third semiconductor chip 123. In at least one example embodiment, the dummy semiconductor chip 130 may be electrically insulated from the first, second, and third semiconductor chips 121, 122, and 123. That is, in at least one example embodiment of the inventive concepts, the dummy semiconductor chip 130 may be electrically insulated from the first, second, and third semiconductor chips 121, 122, and 123, regardless of the presence of the through holes 140 in the third semiconductor chip 123.

In at least one example embodiment, the semiconductor chips 120 may include various microelectronic devices. For example, the semiconductor chips may include metal oxide semiconductor field effect transistors (MOSFETs) (for example, complementary metal oxide semiconductor (CMOS) transistors), system large scale integration (LSI) devices, imaging sensors such as CMOS imaging sensors (CISs), micro-electro-mechanical system (MEMS) devices, active devices, passive devices, and the like.

In response to at least one of the first, second, and third semiconductor chips 121, 122, and 123 being a memory chip, the memory chip may be, for example, a nonvolatile memory chip. More specifically, the memory chip may be a flash memory chip. Even more specifically, the memory chip may be one of a NAND flash memory chip and a NOR flash memory chip. However, the inventive concepts are not limited to this. That is, in at least one example embodiment of the inventive concepts, the memory chip may be one of a phase-change random-access memory (PRAM), magneto-resistive random-access memory (MRAM), and a resistive random-access memory (RRAM).

The dummy semiconductor chip 130 may be on the third semiconductor chip 123 and may be parallel to the third semiconductor chip 123. The dummy semiconductor chip 130 may be insulated by the insulating layers 160 from the substrate 110 and the semiconductor chips 120. The dummy semiconductor chip 130 may not be electrically connected to the third semiconductor chip 123, and may not include a semiconductor circuit (i.e., an active device). That is, in at least one example embodiment of the inventive concepts, the dummy semiconductor chip 130 may include a bare silicon chip with no semiconductor circuit, or a heat sink. Accordingly, the dummy semiconductor chip 130 may be insulated by the insulating layers 160 from the substrate 110 and the semiconductor chips 120. In the semiconductor device 100, which has a desired (and/or alternatively predetermined) thickness h5, the thicknesses of the semiconductor chips 120 may be reduced by increasing the thickness of the dummy semiconductor chip 130, which will be described later in detail.

The thickness h5 of the semiconductor device 100) may be determined in advance. That is, the thickness h5 of the semiconductor device 100 may not change. The sum of thicknesses h1 through h3 of the first, second, and third semiconductor chips 121, 122, and 123 and a thickness h4 of the dummy semiconductor chip 130 may be smaller than the thickness h5 of the semiconductor device 100.

In response to the sum of the thicknesses h1 through h3 of the first, second, and third semiconductor chips 121, 122, and 123 increasing, the thickness h4 of the dummy semiconductor chip 130 may decrease. On the other hand, in response to the sum of the thicknesses h1 through h3 of the first, second, and third semiconductor chips 121, 122, and 123 decreasing, the thickness h4 of the dummy semiconductor chip 130 may increase. That is, by increasing the thickness h4 of the dummy semiconductor chip 130, the thicknesses h1 through h3 of the first, second, and third semiconductor chips 121, 122, and 123 may be relatively reduced.

The thickness h4 of the dummy semiconductor chip 130 may differ from the thickness h1, h2, or h3 of the first, second, or third semiconductor chip 121, 122, or 123. That is, in at least one example embodiment of the inventive concepts, the thickness h4 of the dummy semiconductor chip 130 may be greater than the thickness h1, h2, or h3 of the t, second, or third semiconductor chip 121, 122, or 123.

In at least one example embodiment of the present inventive concepts, the thickness h4 of the dummy semiconductor chip 130 may be smaller than the thickness h1, h2, or h3 of the first, second, or third semiconductor chip 121, 122, or 123. However, the inventive concepts are not limited to this. That is, in at least one example embodiment of the inventive concepts, the thickness h4 of the dummy semiconductor chip 130 may be the same as the thickness h1, h2, or h3 of the first, second, or third semiconductor chip 121, 122, or 123.

In at least one example embodiment, the width L2 of the dummy semiconductor chip may be about the same as the width L1 of the semiconductor chips 120, but the inventive concepts are not limited thereto. That is, in at least one example embodiment of the inventive concepts, the width L2 of the dummy semiconductor chip may differ from the width L1 of the semiconductor chips 120. That is, in at least one example embodiment of the inventive concepts, the width L2 of the dummy semiconductor chip may be larger than the width L1 of the semiconductor chips 120. Alternatively, in at least one example embodiment of the inventive concepts, the width L2 of the dummy semiconductor chip may be smaller than the width L1 of the semiconductor chips 120.

The semiconductor device 100 has been described as including the first, second, and third semiconductor chips 121, 122, and 123, but the inventive concepts are not limited thereto. That is, in at least one example embodiment of the inventive concepts, the semiconductor device 100 may include only one or two semiconductor chips. In other example embodiments, the semiconductor device 100 may include four or more semiconductor chips. When the semiconductor device 100 includes only one or two semiconductor chips, the thickness of the dummy semiconductor chip 130 may be greater than when the semiconductor device 100 includes three semiconductor chips. When the semiconductor device 100 includes four or more semiconductor chips, the thickness of the dummy semiconductor chip 130 may be smaller than when the semiconductor device 100 includes three semiconductor chips.

More specifically, the thickness h5 of the semiconductor device 100 may be determined in advance. Thus, if the number of semiconductor chips provided in the semiconductor device 100 is reduced and the sum of the thicknesses of the semiconductor chips is reduced, the thickness of the dummy semiconductor chip 130 may be increased. On the other hand, if the number of semiconductor chips provided in the semiconductor device 100 is increased and the sum of the thicknesses of the semiconductor chips is increased, the thickness of the dummy semiconductor chip 130 may be reduced.

In at least one example embodiment, the insulating layers 160 may surround the semiconductor chips 120 and the connectors 150. The insulating layers 160 may also surround the lower part of the dummy semiconductor chip 130, but the inventive concepts are not limited thereto. That is, in at least one example embodiment of the inventive concepts, the insulating layers 160 may not surround the lower part of the dummy semiconductor chip 130. In at least one example embodiment of the inventive concepts, the insulating layers 160 may surround only some of the semiconductor chips 120.

The insulating layers 160 may contain, for example, pre-metal dielectric (PMD) layers. The insulating layers 160 may be formed using a low-dielectric constant material such as FOX, TOSZ, USG, BSG, PSG, BPSG, PRTEOS, FSG, HDP, PEOX, FCVD, or a combination thereof.

In at least one example embodiment, the insulating layers 160 may be among the first, second, and third semiconductor chips 121, 122, and 123 so that the first, second, and third semiconductor chips 121, 122, and 123 can be electrically connected only via the TSVs and the connectors 150. The insulating layers 160 may also be between the third semiconductor chip 123 and the dummy semiconductor chip 130. The insulating layers 160 may insulate the third semiconductor chip 123 and the dummy semiconductor chip 130 from each other.

The passivation layer 170 may be on the substrate 110 and may surround the sides of each of the insulating layers 160 and the sides of the dummy semiconductor chip 130. In response to the insulating layers 160 being formed to only partially surround the semiconductor chips 120, the passivation layer 170 may surround parts of the semiconductor chips 120 that are not surrounded by the insulating layers 160, the sides of each of the insulating layers 160, and the sides of the dummy semiconductor chip 130. The passivation layer 170 may not be on the top surface of the dummy semiconductor chip 130, but the inventive concepts are not limited thereto. That is, in at least one example embodiment of the inventive concepts, the passivation layer 170 may cover the top surface of the dummy semiconductor chip 130.

The passivation layer 170 may protect the semiconductor chips 120 from the outside of the semiconductor device 100. Accordingly, the passivation layer 170 may contain an insulating material, such as an epoxy mold compound or silicon.

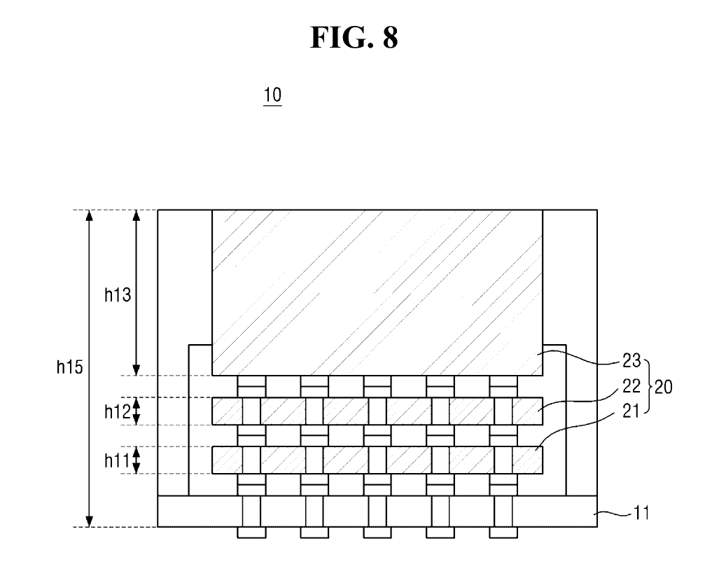

The benefits of a semiconductor device obtained by the fabricating method according to the at least one example embodiment, as shown in FIGS. 1 to 6, i.e., the semiconductor device 100, will hereinafter be described with reference to FIG. 8. A semiconductor device 10 to be compared with the semiconductor device 100 will hereinafter be described with reference to FIG. 8, focusing mainly on differences with the semiconductor device 100.

FIG. 8 is a cross-sectional view for explaining the benefits of the semiconductor device 100.

In at least one example embodiment, as shown in FIG. 8, the semiconductor device 10 may include a substrate 11, a first semiconductor chip 21, a second semiconductor 22, and a third semiconductor chip 23. The semiconductor device 10 may not include the dummy semiconductor chip 130. In order to uniformly maintain a desired (and/or alternatively predetermined) thickness h15 of the semiconductor device 10, the third semiconductor chip 23 may have a relatively thick thickness h13. As a result, the width of a scribe lane for wafer sawing in the process of providing the third semiconductor chip 23 may increase.

Accordingly, the number of semiconductor chips that can be fabricated on a wafer, i.e., the net die per wafer, may be reduced, thereby causing disadvantages during the fabrication of semiconductor chips. On the other hand, in the semiconductor device 100, the dummy semiconductor chip 130 is disposed on the semiconductor chips 120, and the thicknesses of the semiconductor chips 120 can be reduced by increasing the thickness of the dummy semiconductor chip 130 in the semiconductor device 100, which has a predefined thickness that is determined in advance. Accordingly, the net die per wafer can be increased, thereby reducing disadvantages that may be caused during the fabrication of semiconductor chips.

The semiconductor device 100 has been described above as having a desired (and/or alternatively predetermined) thickness that is determined in advance, but the inventive concepts are not limited thereto. That is, in at least one example embodiment, even if the thickness of the semiconductor device 100 is not determined in advance, the thickness of the semiconductor chips 120 may be reduced by increasing the thickness of the dummy semiconductor chip 130. Thus, the inventive concepts may be beneficial to the fabrication of semiconductor chips even when the thickness of a semiconductor device is not determined in advance.

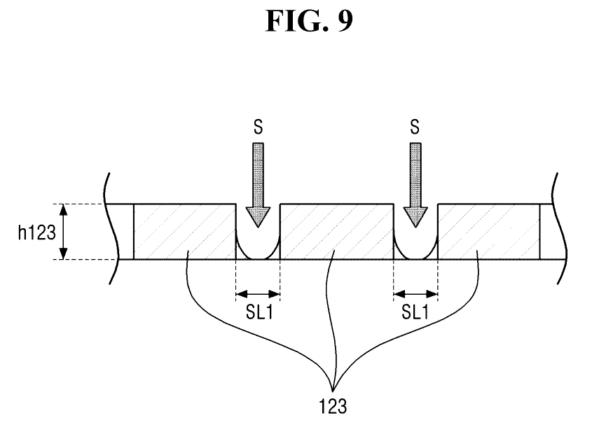

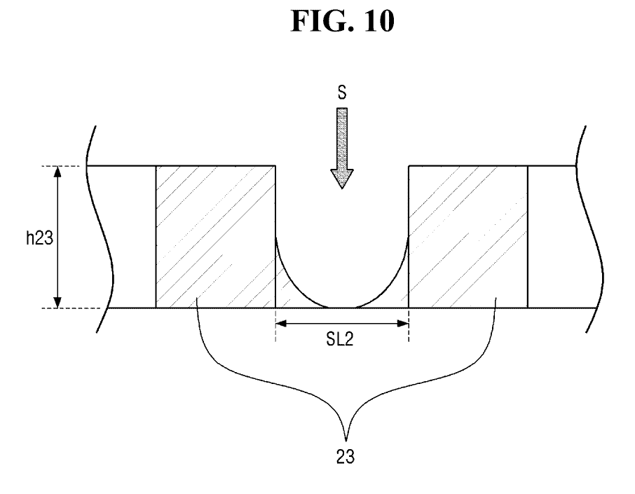

The width of a scribe lane of a semiconductor wafer according to the thickness of a semiconductor chip will hereinafter be described with reference to FIGS. 9 and 10.

FIGS. 9 and 10 are cross-sectional views of a width of a scribe lane of a semiconductor wafer according to the thickness of a semiconductor chip in the fabricating method according to at least one example embodiment.

In at least one example embodiment, as shown in FIG. 9, the third semiconductor chip 123 of the semiconductor device 100 may have a relatively small thickness h123 due to the presence of the dummy semiconductor chip 130. Accordingly, during a sawing process in the forming the third semiconductor chip 123, a scribe lane width SL1 may be relatively small. Thus, the number of semiconductor chips that can be formed on a wafer may increase.

In at least one example embodiment, as shown in FIG. 10, the third semiconductor chip 23 of the semiconductor device 10 may have a relatively large thickness h23 due to the absence of the dummy semiconductor chip 130. Accordingly, during a sawing process in the forming the third semiconductor chip 23, a scribe lane width SL2 may be relatively small. Thus, the number of semiconductor chips that can be formed on a wafer may decrease.

In at least one example embodiment, due to the presence of the dummy semiconductor chip 130 in the semiconductor device 100, the thicknesses of the semiconductor chips 120 may be reduced, and by increasing the thickness h4 of the dummy semiconductor chip 130, the semiconductor chip 120 may be formed to have a relatively small thickness. Thus, the number of semiconductor chips that can be formed on a wafer may increase, and as a result, any disadvantages that may be caused during the fabrication of semiconductor chips may be reduced.

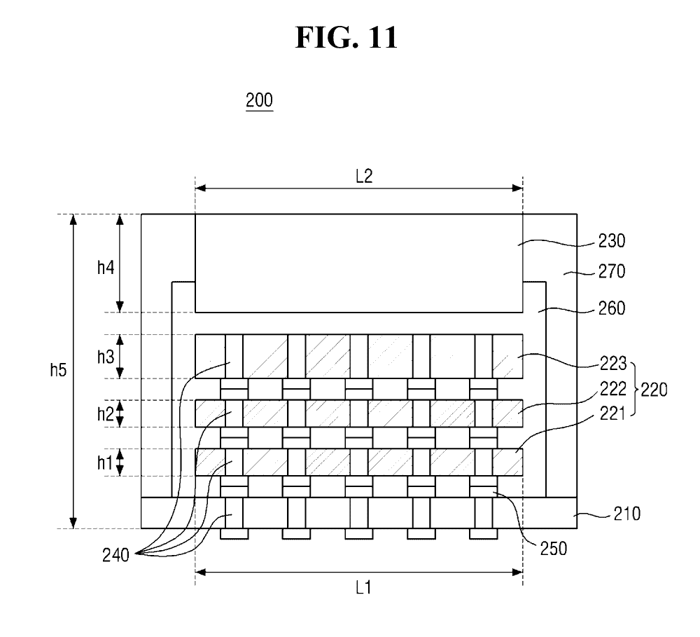

A semiconductor device according to at least one example embodiment of the inventive concepts will hereinafter be described with reference to FIG. 11, focusing mainly on differences with the semiconductor device 100.

FIG. 11 is a cross-sectional view of a semiconductor device according to at least one example embodiment.

In at least one example embodiment, as shown in FIG. 11, in a semiconductor device 200, unlike in the semiconductor device 100 of FIG. 1, through holes 240 may be provided in a third semiconductor chip 223. In the semiconductor device 200, like in the semiconductor device 100, a dummy semiconductor chip 230 may be electrically insulated from a first semiconductor chip 221, a second semiconductor chip 222, and the third semiconductor chip 223.

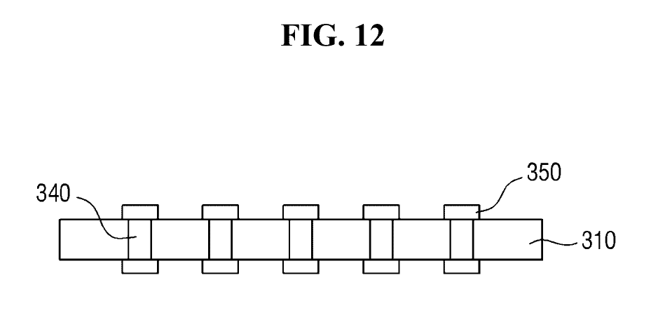

A fabricating method of a semiconductor device, according to at least one example embodiment of the inventive concepts, and a semiconductor device obtained by the fabricating method will hereinafter be described with reference to FIGS. 12 to 19, focusing mainly on differences with the fabricating method.

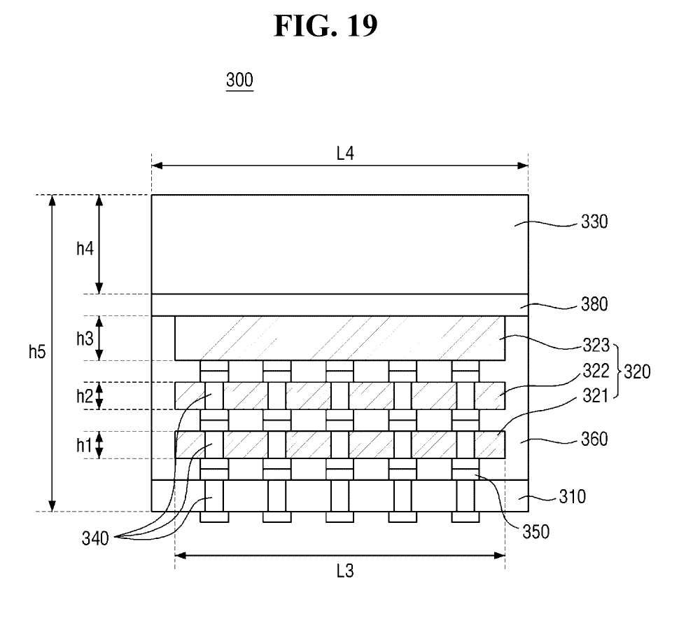

FIGS. 12 to 18 are cross-sectional views illustrating intermediate operations of a fabricating method of a semiconductor device, according to at least one example embodiment of the inventive concepts. FIG. 19 is a cross-sectional view of a semiconductor device obtained by the fabricating method according to the at least one example embodiment as shown in FIGS. 12 to 18.

Referring to FIG. 12, through holes 140 may be formed to penetrate a substrate 310 in a direction perpendicular to the horizontal plane of the substrate 110. After the formation of the through holes, connectors 350 may be formed on the top and bottom surfaces of the substrate 310 to be each connected to both ends of a corresponding through hole 340.

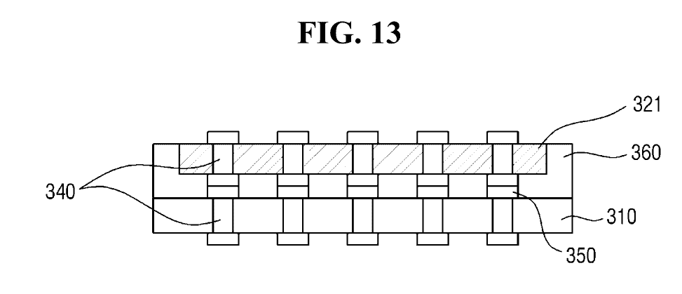

Referring to FIG. 13, connectors 350 and the first semiconductor chip 321 may be formed on the substrate 310. Thereafter, an insulating layer 360 may be formed on the substrate 310 to surround the connectors 350 formed on the bottom surface of the first semiconductor chip 321 and the first semiconductor chip 321. The insulating layer 360 of FIG. 13, unlike the insulating layer 160 of FIG. 3, may overlap the substrate 310.

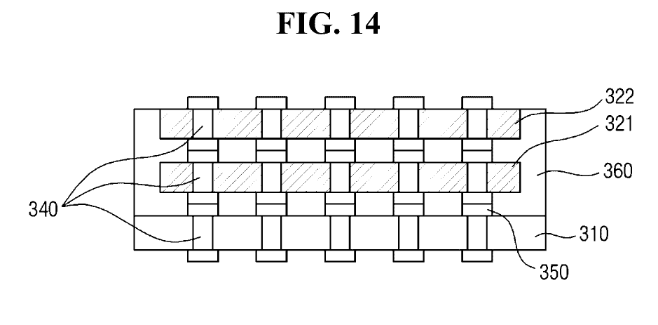

Referring to FIG. 14, connectors 350 and the second semiconductor chip 322 may be formed on the first semiconductor chip 321. Thereafter, an insulating layer 360 may be formed on the first semiconductor chip 321 and the insulating layer 360 of FIG. 13. The insulating layer 360 may surround the connectors 350 formed on the bottom surface of the second semiconductor chip 322 and the second semiconductor chip 322. The insulating layer 360 of FIG. 14, unlike the insulating layer 160 of FIG. 4, may overlap the substrate 310.

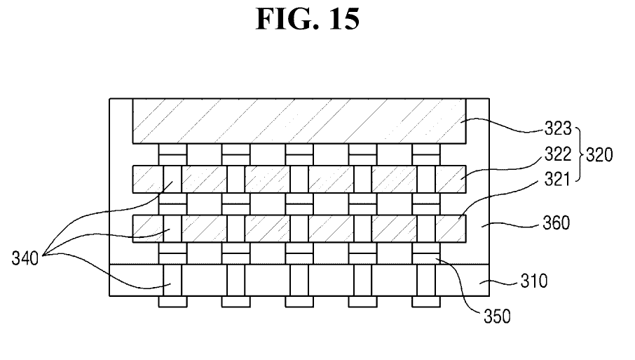

Referring to FIG. 15, connectors 350 and the third semiconductor chip 323 may be formed on the second semiconductor chip 322. An insulating layer 360 may be formed on the second semiconductor chip 322 and the insulating layer 360 of FIG. 14. The insulating layer 360 may surround the connectors 350 formed on the bottom surface of the third semiconductor chip 323 and the third semiconductor chip 323. The insulating layer 360 of FIG. 15, unlike the insulating layer 160 of FIG. 5, may overlap the substrate 310.

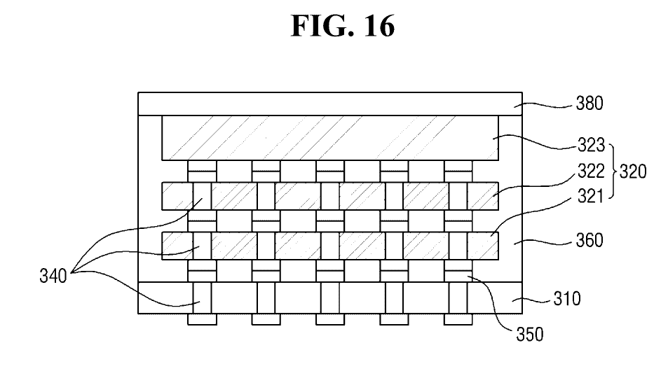

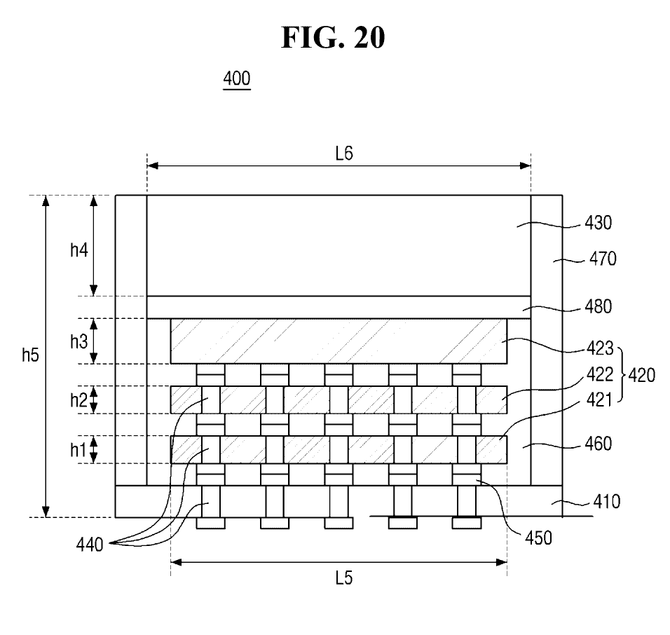

Referring to FIG. 16, in the fabricating method according to the at least one example embodiment, as shown in FIGS. 12 to 18, unlike in the fabricating method according to the at least one example embodiment shown in FIGS. 1 to 6, an adhesive layer 380 may be formed on the third semiconductor chip 323 and the insulating layer 360 of FIG. 15 to overlap the substrate 310. A semiconductor device 300 of FIG. 19, unlike the semiconductor device 100 of FIG. 7, may not include any passivation layer. Alternatively. the semiconductor device 300 of FIG. 19 may be configured to include a passivation layer 470, in which case, the semiconductor device 300 may be formed as shown in FIG. 20, i.e., a semiconductor device according to at least one example embodiment of the inventive concepts may be obtained.

The adhesive layer 380 may bond the third semiconductor chip 323 and the dummy semiconductor chip 330 together. The adhesive layer 380 may contain a nonconductive material. The adhesive layer 280 may insulate the third semiconductor chip 323 and the dummy semiconductor chip 330 from each other.

The dummy semiconductor chip 330 may be formed on the adhesive layer 380 and may overlap the substrate 310. The dummy semiconductor chip 330 may be formed through wafer-to-wafer bonding, which will be described later in detail, but the inventive concepts are not limited thereto. That is, in at least one example embodiment of the inventive concepts, the dummy semiconductor chip 330 may be formed on the adhesive layer separately.

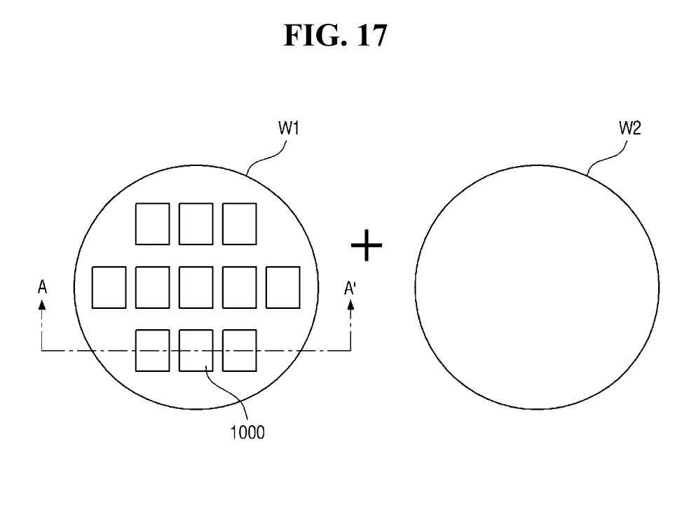

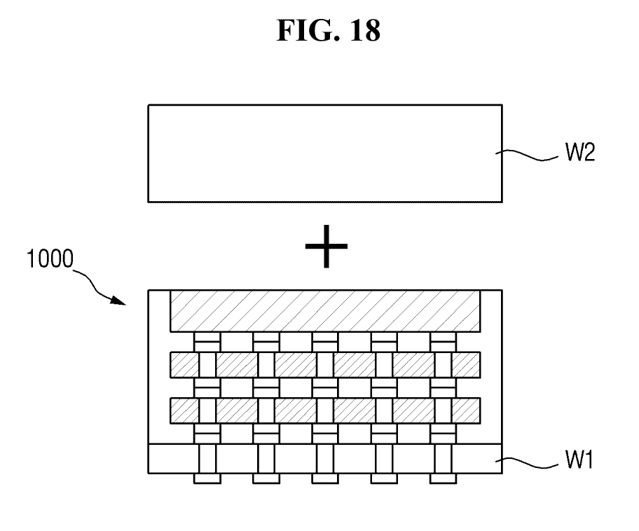

FIG. 17 is a schematic view illustrating semiconductor devices 1000 according to at least one example embodiment of the inventive concepts, which is fabricated by wafer-to-wafer bonding, and FIG. 18 is an enlarged cross-sectional view of one of the semiconductor devices 1000 of FIG. 17, taken along line A-A′ of FIG. 17.

In at least one example embodiment, as shown in FIGS. 17 and 19, the semiconductor devices 1000 may be arranged at regular intervals on a semi conductor wafer W1. Each of the semiconductor devices 1000, like the semiconductor device 300 of FIG. 19, may include a substrate 310, a first semiconductor chip 321, a second semiconductor chip 322, a third semiconductor chip 323, through holes 340, connectors 350, and insulating layers 360.

In at least one example embodiment, a dummy semiconductor wafer W2 may not include any semiconductor circuit (i.e., an active element). That is, the dummy semiconductor wafer W2 may include a silicon chip with no semiconductor circuit, or a heat sink.

FIG. 18 illustrates a partial enlarged view of one of the semiconductor devices 1000 on the semiconductor wafer W1.

In at least one example embodiment, as shown in FIG. 18, the dummy semiconductor wafer W2 may be coupled onto the semiconductor wafer W1 where the semiconductor devices 1000 are arranged at regular intervals. The semiconductor devices 1000 and the dummy semiconductor wafer W2 may be bonded to each other through the adhesive layer 380.

After the bonding of the dummy semiconductor wafer W2 onto the semiconductor devices 1000, the semiconductor wafer W1 and the dummy semiconductor wafer W2 may be sawn, thereby obtaining the semiconductor device 300. The fabricating method according to at least one example embodiment as shown in FIGS. 12 to 18 is advantageous in that the semiconductor wafer W1 and the dummy semiconductor wafer W2 can be sawn by a single process, rather than by separate processes.

The semiconductor device 300 of FIG. 19 may be obtained by the fabricating method according to the at least one example embodiment shown in FIGS. 12 to 18. The fabricating method according to the at least one example embodiment shown in FIGS. 12 to 18 has been described as determining the thickness of the semiconductor device 300 in advance, but the inventive concepts are not limited thereto.

A semiconductor device obtained by the fabricating method according to the at least one example embodiment shown in FIGS. 12 to 18, i.e., the semiconductor device 300, will hereinafter be described with reference to FIG. 19, focusing mainly on differences with the semiconductor devices 100 and 200.

In at least one example embodiment, as shown in FIG. 19, the semiconductor device 300 may include the substrate 310, the first semiconductor chip 321, the second semiconductor chip 322, the third semiconductor chip 323, the dummy semiconductor chip 330, the through holes 340, the connectors 350, the insulating layers 360, and the adhesive layer 380. The semiconductor device 300, unlike the semiconductor device of FIG. 7, may include the adhesive layer 380, but may not include the passivation layer 170.

In at least one example embodiment, the adhesive layer 380 may be disposed on the third semiconductor chip 323 and the insulating layers 360, and may bond the third semiconductor chip 323 and the dummy semiconductor chip 330 together. The adhesive layer 380 may contain a nonconductive material. The adhesive layer 380 may insulate the third semiconductor chip 323 and the dummy semiconductor chip 330 from each other.

In at least one example embodiment, the dummy semiconductor chip 330 may be on the adhesive layer 380. The dummy semiconductor ship 330 may not be surrounded by the insulating layers 360. The dummy semiconductor chip 330 may overlap the substrate 310. A width L4 of the dummy semiconductor chip 330 may be larger than a width L3 of the first, second, and third semiconductor chips 321, 322, and 323. The semiconductor device 300 may be fabricated by wafer-to-wafer bonding.

In at least one example embodiment, the third semiconductor chip 323 may include the through holes 340, but may still be electrically insulated from the first, second, and third semiconductor chips 321, 322, and 323.

A semiconductor device according to at least one example embodiment of the inventive concepts will hereinafter be described with reference to FIG. 20, focusing mainly on differences with the semiconductor devices 100, 200, and 300.

FIG. 20 is a cross-sectional view of a semiconductor device according to at least one example embodiment of the inventive concepts.

In at least one example embodiment, as shown in FIG. 20, a semiconductor device 400, unlike the semiconductor device 300 of FIG. 19, may further include a passivation layer 470.

In at least one example embodiment, the passivation layer 470 may be formed on a substrate 410 and may surround the sides of each of a plurality of insulating layers 460, the sides of an adhesive layer 480, and the sides of a dummy semiconductor chip 430. In response to the insulating layers 460 being formed to only partially surround semiconductor chips 420, the passivation layer 470 may surround parts of the semiconductor chips 420 that are not surrounded by the insulating layers 460. The passivation layer 470 may not be formed on the top surface of the dummy semiconductor chip 430, but the inventive concepts are not limited thereto.

In at least one example embodiment, the passivation layer 470 may protect the semiconductor chips 420 from the outside of the semiconductor device 400. Accordingly, the passivation layer 470 may contain an insulating material, such as an epoxy mold compound or silicon.

In at least one example embodiment, a width L6 of the dummy semiconductor chip 430 may be larger than a width L5 of the semiconductor chips. The semiconductor device 400 may be fabricated by wafer-to-wafer bonding, as described above with reference to FIGS. 17 and 18. In this case, the semiconductor device 400 may be fabricated by sawing a semiconductor wafer W1 and a dummy semiconductor wafer W2 and then forming the passivation layer 470 on the substrate 410 to surround the sides of each of the insulating layers 460, the sides of the adhesive layer 480, and the sides of the dummy semiconductor chip 430.

In at least one example embodiment, a third semiconductor chip 423 may include through holes 440, but may still be electrically insulated from a first semiconductor chip 421, a second semiconductor chip 422, and the third semiconductor chip 423.

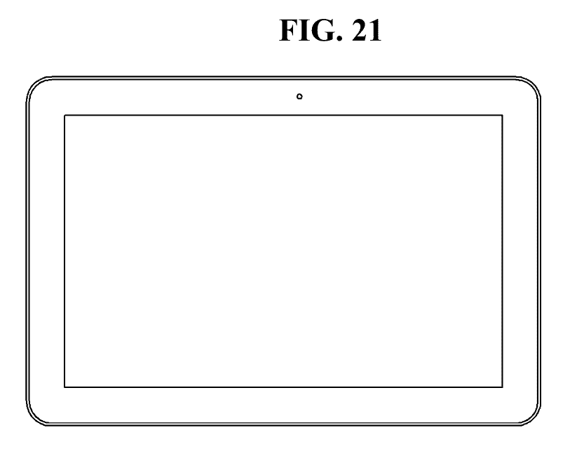

FIG. 21 is a schematic view of at least one example embodiment of a semiconductor system to which a semiconductor device according to at least one example embodiment of the inventive concepts can be applied. More specifically, FIG. 21 illustrates a tablet personal computer (PC). A semiconductor device according to at least one example embodiment of the inventive concepts may be used in a tablet PC. It is obvious that a semiconductor device according to at least one example embodiment of the inventive concepts may also be used in various integrated circuit (IC) devices other than that set forth herein.

Although at least some example embodiments of the inventive concepts have been described with reference to a number of illustrative example embodiments of the present inventive concepts thereof, it should be understood that numerous other modifications and example embodiments of the inventive concepts may be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A fabricating method of a semiconductor device, in which a first semiconductor chip having a first thickness and a semiconductor chip having a second thickness are used to fabricate a semiconductor device having a third thickness that is greater than the sum of the first and second thicknesses, the fabricating method comprising:
providing the first semiconductor chip having the first thickness;
providing the second semiconductor chip on the first semiconductor chip, the second semiconductor chip connected to the first semiconductor chip by through silicon vias (TSVs), and the second semiconductor chip having the second thickness; and
providing a dummy semiconductor chip on the second semiconductor chip, the dummy semiconductor chip not electrically connected to the second semiconductor chip, and the dummy semiconductor chip having a fourth thickness,
wherein the fourth thickness is about a difference between the third thickness and a sum of the first and second thicknesses.

2. The fabricating method of claim 1, further comprising:
forming an insulating layer to surround the first and semiconductor chips; and
forming a passivation layer to surround the insulating layer and the dummy semiconductor chip.

3. The fabricating method of claim 1, wherein the fourth thickness is different from the first and second thicknesses.

4. The fabricating method of claim 3, wherein the fourth thickness is larger than the first and second thicknesses.

5. The fabricating method of claim 1, wherein the TSVs are formed to penetrate the first semiconductor chip, but not the second semiconductor chip.

6. The fabricating method of claim 1, wherein the dummy semiconductor chip is a bare silicon (Si) chip.

7. The fabricating method of claim 1, further comprising:
providing a third semiconductor chip between the first and second semiconductor chips, the third semiconductor chip having a fifth thickness,
wherein the third semiconductor chip is connected to the first and second semiconductor chips via TSVs, and the fourth thickness is generated based on about a difference between about the third thickness and a sum of the first, second, and fifth thicknesses.

8. The fabricating method of claim 7, wherein the fifth thickness is the same as the first thickness.

9. The fabricating method of claim 1, wherein the providing the dummy semiconductor chip, comprises:
forming an adhesive layer between the second semiconductor chip and the dummy semiconductor chip to bond the second semiconductor chip and the dummy semiconductor chip together.

10. The fabricating method of claim 9, further comprising:
forming an insulating layer to surround the first and second semiconductor chips; and
forming a passivation layer to surround the insulating layer, the adhesive layer, and the dummy semiconductor chip.

11. A fabricating method of a semiconductor device, the fabricating method comprising:
providing first and second semiconductor chips, which are horizontally spaced from each other on a wafer, each of the first and second semiconductor chips having a first thickness,
connecting each of the first and second semiconductor chips to the wafer via through silicon vias (TSVs);
providing a dummy wafer on the first and second semiconductor chips, the dummy wafer not electrically connected to the first and second semiconductor chips, and the dummy wafer having a second thickness; and
providing a first semiconductor device including the first semiconductor chip and a second semiconductor device including the second semiconductor chip by sawing through the wafer and the dummy wafer,
the first and second semiconductor devices having about a third thickness; and the second thickness is about a difference between the third thickness the first thickness.

12. The fabricating method of claim 11, wherein the providing the dummy wafer, comprises:
forming an adhesive layer between the first and second semiconductor chips and between the dummy wafer and at least one of the first semiconductor and the second semiconductor chip.

13. The fabricating method of claim 11, wherein a width of the dummy wafer, which overlaps the first semiconductor device, is different from a width of the first semiconductor chip.

14. The fabricating method of claim 13, wherein the width of the dummy wafer, which overlaps the first semiconductor device, is larger than the width of the first semiconductor chip.

15. The fabricating method of claim 11, wherein the dummy wafer does not include a semiconductor circuit.

16. A method of fabricating a semiconductor device, the method comprising:
providing at least two semiconductor chips on a substrate, the at least two semiconductor chips having a combined first thickness;
electrically connecting the at least two semiconductor chips;
providing a dummy semiconductor chip on one of the at least two semiconductor chips, the dummy semiconductor chip having a second thickness;
providing at least one semiconductor device having a desired third thickness, the desired third thickness greater than the first thickness;
wherein the second thickness is about a difference between the third thickness and the combined first thickness.

17. The method of claim 16, wherein the at least two semiconductor chips are electrically connected via through silicon vias.

18. The method of 16, further comprising:
forming an insulating layer at least partially around the at least two semiconductor chips.

19. The method of claim 18, further comprising:
forming a passivation layer at least partially around the insulating layer and the dummy semiconductor chip.

20. The method of claim 16, wherein a width of the dummy semiconductor chip, which overlaps the semiconductor device, is different from a width of the at least one semiconductor chip.
